(19) United States
(12) Patent Application Publication
(10) Pub. No.: US 2007/0033496 A1
(43) Pub. Date: Feb. 8, 2007

(54) System and method for adjusting BER/PER to increase network stream-based transmission rates

(75) Inventors: Todor Cooklev, Moraga, CA (US); Clifford Tavares, San Diego, CA (US)

Correspondence Address: THELEN REID BROWN RAYSMAN & STEINER LLP, 303 TWIN DOLPHIN DRIVE, SUITE 600, REDWOOD SHORES, CA, 94065, US

(73) Assignee: Hitachi, Ltd.

(21) Appl. No.: 11/429,020

(22) Filed: May 4, 2006

Related U.S. Application Data
(60) Provisional application No. 60/699,825, filed on Jul. 14, 2005.

(51) Int. Cl. H03M 13/00

(52) U.S. Cl. 714/776

(57) ABSTRACT

A transmitting method obtains a data packet of a data-type to be transmitted via a computer network to a receiving system; appends a retry flag to the data packet, the retry flag based on the data-type, the retry flag indicating whether the receiving system may attempt a retransmission; and transmits the data packet to the receiving system. When the data-type is one of voice, video or audio data, the retry flag may indicate that the receiving system should not attempt retransmission. The method may also comprise appending an error-correction algorithm ID based on the data-type to the data packet. A receiving method receives the data packet; and when a bit or packet error is identified then initiating a retransmission if the retry flag so commands. When the retry flag indicates that a retransmission should not occur, the receiving method may initiate an error correction algorithm identified in the data packet.

### PRIORITY CLAIM

This application claims benefit of and hereby incorporates by reference provisional patent application Ser. No. 60/699,825, entitled “System and Method for Using BER/PER to Increase Network Stream-Based Transmission Rates,” filed on Jul. 14, 2005, by inventors Tavares and Cooklev.

### TECHNICAL FIELD

This invention relates generally to data communication over digital networks, and more particularly provides a system and method for adjusting BER/PER to increase network stream-based transmission rates.

### BACKGROUND

Traditionally, communication networks allocate bandwidth using a first-come, first-serve policy and try to accommodate every request, regardless of the nature of the request. If there insufficient bandwidth, the request can be denied.

Recently, data communications technologies are increasingly being used not only to transport general data, but also to transport multimedia data, e.g., voice, audio, and/or video data. However, multimedia streams have different delivery constraints than genera data (e.g., jitter, latency, error rate). Unfortunately, traditional communication networks have no special mechanisms to meet these requirements.

Providing different levels of quality of service (QoS) is widely recognized as one of the most important ways to improve transport of multimedia data. The main QoS factors are bandwidth, latency, jitter, packet loss, and service availability. QoS is also a business issue. Some business requirements wish to offer service differentiation and service availability.

The effects of bandwidth, latency and jitter have been studied. For example, to maintain tolerable real-time voice communication, end-to-end delay (latency) for voice packets must be less than 250 ms. If a packet arrives with a delay exceeding 250 ms, the packet may be discarded since it lost its real-time meaning. Some systems address latency by signal processing and protocol improvements. Some embodiments improve jitter by buffering, although a large buffer may create latency problems.

It should be noted that real-time traffic relaxes certain requirements imposed by general data traffic. In particular, real-world signals such as audio and video are somewhat tolerant of bit errors. Voice and video quality are not severely affected by the occasional bit error. However, in LANs, bit error tolerance is irrelevant. That is, packets are discarded even if only a single bit is in error and discarded packets are retransmitted regardless of tolerance.

In wireless networks, bandwidth is at a significant premium. Since delayed packets lose their real-time meaning, retransmission of real-time data in wireless networks is highly unnecessary and undesirable.

Therefore, a system and method that improves the use of bandwidth in communication networks, and especially in wireless networks, are highly needed.

### SUMMARY

Embodiments of the present invention provide an enhancement of quality of service (QoS) mechanisms in wired and wireless systems. In one embodiment, the present invention provides a method to improve the treatment of media streams by applying different error correction algorithms, e.g., forward error correction (FEC) codes. In one embodiment, the present invention provides a new metric, i.e., data-type, to control network transmission protocols, to be applied in the MAC layer or in the physical layer. By examining data-type (e.g., as it relates to BER/PER) to define acceptable error rates and selecting error correction algorithms accordingly, a network system may be capable of offering greater network speed to multimedia data, e.g., video, voice and/or audio. Certain embodiments of the present invention may reduce jitter, reduce latency, enhance average throughput for multimedia streams, and maintain compatibility with traditional priority levels.

Networks handle streams of two different types, namely, general data (FTP, internet, etc.) and multimedia data (IP phones, video conferencing, music streaming, etc.). As stated above, the requirements for these data-types are different. For example, general data requires zero packet error rate (PER) and bit error rate (BER) (in the MAC or upper layers), whereas multimedia streams may have non-zero PER and BER (in the MAC or upper layers). If, after decoding a multimedia packet, a few bits are in error, the multimedia packet need not be thrown away. A human observer usually cannot detect a few bits in error in a video, audio or voice signal. Also, there are error-concealment techniques that can “mask” a few bits in error. Further, since video, audio and voice are real-time processes, a late but correct data packet has less value than an original packet with one or more bits in error.

In one embodiment, a method comprises obtaining a data packet of a data-type to be transmitted via a computer network to a receiving system; appending a retry flag to the data packet, the retry flag being based on the data-type, the retry flag indicating whether the receiving system should attempt a retransmission when an error is presumed in the data packet; and transmitting the data packet with the appended retry flag via the computer network to the receiving system. When the data-type is one of voice, video or audio data, the retry flag may indicate that the receiving system should not attempt retransmission when an error is presumed in the data packet. The method may also comprise appending error-detection information to the data packet, the error-detection information to be used for validation against the data packet by the receiving system, a failure of validation enabling the receiving system to presume an error in the data packet. The error-detection information may include CRC information. The method may also comprise appending an error-correction algorithm ID to the data packet. The method may also comprise selecting the error-correction algorithm ID to be appended to the data packet based on the data-type. The method may also comprise using an error-correction algorithm to generate error-correction information associated with the data packet, the error-correction information intended to enable the receiving system to correct an error presumed in the data packet; and transmitting the error-correction information associated with the data packet to the receiving system.

In another embodiment, a system comprises an upper layer communication module for obtaining a data packet of a data-type to be transmitted via a computer network to a receiving system; a header encoder for appending a retry flag to the data packet, the retry flag being based on the data-type, the retry flag indicating whether the receiving system should attempt a retransmission when an error is presumed in the data packet; and a physical layer for transmitting the data packet with the appended retry flag via the computer network to the receiving system. When the data-type is one of voice, video or audio data, the retry flag may indicate that the receiving system should not attempt retransmission when an error is presumed in the data packet. The header encoder may append error-detection information to the data packet, the error-detection information to be used for validation against the data packet by the receiving system, a failure of validation enabling the receiving system to presume an error in the data packet. The error-detection information may include CRC information. The header encoder may append an error-correction algorithm ID to the data packet. The header encoder may access a QoS model defining which error-correction algorithm ID to append to the data packet based on the data-type. The system may further comprise an error-correction module for using an error-correction algorithm to generate error-correction information associated with the data packet, the error-correction information intended to enable the receiving system to correct an error presumed in the data packet; and the physical layer may transmit the error-correction information associated with the data packet to the receiving system.

In another embodiment, a method comprises receiving a data packet having error-detection information and a retry flag; validating the error-detection information against the data packet; when the error-detection information fails to validate, presuming that the data packet contains an error; and when presuming that the data packet contains an error, initiating a retransmission if the retry flag indicates that a retransmission should occur and not initiating a retransmission if the retry flag indicates that a retransmission should not occur. The method may further comprise when presuming that the data packet contains an error and the retry flag indicates that a retransmission should not occur, initiating an error correction algorithm to attempt to correct the error. The data packet may have an error-correction algorithm ID that identifies the error correction algorithm.

In another embodiment, a system comprises a physical layer for receiving a data packet having error-detection information and a retry flag; an error checking module for validating the error-detection information against the data packet and presuming that the data packet contains an error when the error-detection information fails to validate; a retransmission manager for initiating a retransmission when presuming that the data packet contains an error and the retry flag indicates that a retransmission should occur, and not initiating a retransmission when presuming that the data packet contains an error and the retry flag indicates that a retransmission should not occur. The system may further comprise an error correction module for initiating an error correction algorithm to attempt to correct the error when presuming that the data packet contains an error and the retry flag indicates that a retransmission should not occur. The data packet may have an error-correction algorithm ID that identifies the error correction algorithm.

### BRIEF DESCRIPTION OF THE DRAWINGS

FIG. 1 is a block diagram of a network architecture, in accordance with an embodiment of the present invention.

FIG. 2 is a block diagram illustrating details of a packet, in accordance with an embodiment of the present invention.

FIG. 3 is a table illustrating a two-dimensional quality of service model, in accordance with an embodiment of the present invention.

FIG. 4 is a block diagram illustrating details of a packet encoder, in accordance with an embodiment of the present invention.

FIG. 5 is a block diagram illustrating details of a packet decoder, in accordance with an embodiment of the present invention.

FIG. 6 is a block diagram illustrating details of a computer system.

FIG. 7 is a flowchart illustrating a method of encoding and transmitting data packets, in accordance with an embodiment of the present invention.

FIG. 8 is a flowchart illustrating a method of receiving and decoding data packets, in accordance with an embodiment of the present invention.

### DETAILED DESCRIPTION

The following description is provided to enable any person skilled in the art to make and use the invention, and is provided in the context of a particular application and its requirements. Various modifications to the embodiments are possible to those skilled in the art, and the generic principles defined herein may be applied to these and other embodiments and applications without departing from the spirit and scope of the invention. Thus, the present invention is not intended to be limited to the embodiments shown, but is to be accorded the widest scope consistent with the principles, features and teachings disclosed herein.

Embodiments of the present invention provide an enhancement of quality of service (QoS) mechanisms in wired and wireless systems. In one embodiment, the present invention provides a method to improve the treatment of media streams by applying different error correction algorithms, e.g., forward error correction (FEC) codes. In one embodiment, the present invention provides a new metric, i.e., data-type, to control network transmission protocols, to be applied in the MAC layer or in the physical layer. By examining data-type (e.g., as it relates to BER/PER) to define acceptable error rates and selecting error correction algorithms accordingly, a network system may be capable of offering greater network speed to multimedia data, e.g., video, voice and/or audio. Certain embodiments of the present invention may reduce jitter, reduce latency, enhance average throughput for multimedia streams, and maintain compatibility with traditional priority levels.

Networks handle streams of two different types, namely, general data (FTP, internet, etc.) and multimedia data (IP phones, video conferencing, music streaming, etc.). As stated above, the requirements for these data-types are different. For example, general data requires zero packet error rate (PER) and bit error rate (BER) (in the MAC or upper layers), whereas multimedia streams may have non-zero PER and BER (in the MAC or upper layers). If, after decoding a multimedia packet, a few bits are in error, the multimedia packet need not be thrown away. A human observer usually cannot detect a few bits in error in a video, audio or voice signal. Also, there are error-concealment techniques that can “mask” a few bits in error. Further, since video, audio and voice are real-time processes, a late but correct data packet has less value than an original packet with one or more bits in error.

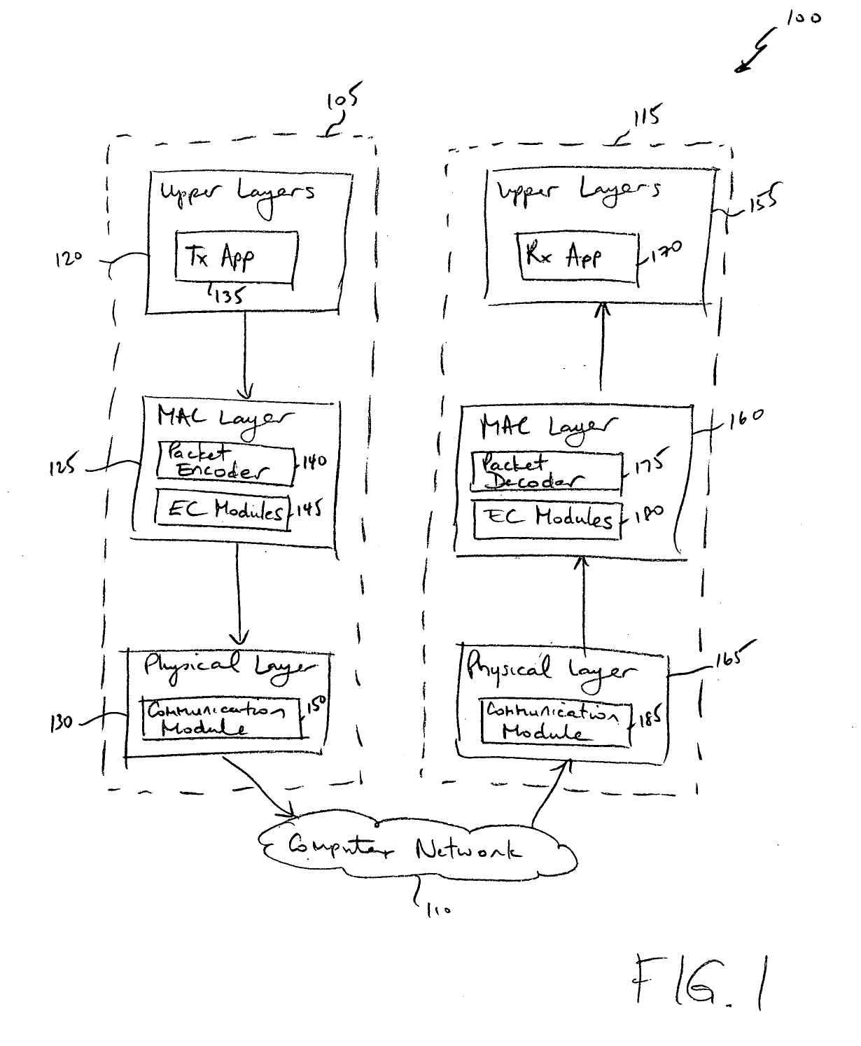

FIG. 1 is a block diagram of a network architecture 100, in accordance with an embodiment of the present invention. Network architecture 100 includes a transmitting (TX) computer system 105 coupled via a computer network 110 to a receiving (RX) computer system 115. The transmitting computer system 105 includes upper layers 120, coupled to a MAC layer 125, coupled to a physical layer 130, which is coupled to a computer network 110. The receiving computer system 115 includes upper layers 155, coupled to a MAC layer 160, coupled to a physical layer 165, which is coupled to the computer network 110. While each of computer 105 and computer 115 may be identical, capable of bidirectional communication, for convenience, computer 105 is being described as the transmitter and computer 115 is being described as the receiver. In this example case, data flows from the upper layers 120 of the transmitting computer system 105 down through the lower layers via the computer network 110 and up through the lower layers of the receiving computer system 115 until it reaches the upper layers 155.

The upper layers of the transmitting computer system 105 includes a data transmission (TX) application (e.g., a video streaming engine, an instant messenger application, an audio streaming application, an internet telephone, a web server, or the like) 135, e.g., in the application layer. The transmitting application 135 sends data to the MAC layer 125. The data may be general data, e.g., a web page of a website, or multimedia data, e.g., voice, video and/or audio. The upper layers 120 may append priority information to the data for prioritization of transmission.

The MAC layer 125 of the transmitting computer system 105 includes a packet encoder 140 and a set of error correction (EC) modules 145. The packet encoder 140 receives the data from transmitting application 135 of the upper layers 120, and based on the data-type selects a particular EC module 145 to apply to the packet generation protocol. For example, if the packet encoder 140 determines that the data-type is general data, the packet encoder 140 may select an EC module 145 effecting an EC algorithm that has higher BER/PER (e.g., parity check only) and higher latency (lower priority). If the packet encoder 140 determines that the data-type is multimedia, the packet encoder 140 may select an EC module 145 effecting an EC algorithm that has lower BER/PER (e.g., FEC, check bits, Viterbi algorithms, redundancy checks, etc.) and lower latency (higher priority). Similarly, the packet encoder 140 can differentiate between different types of general data and different types of multimedia data. Different data-types may use different error checking algorithms. One data-type may use a plurality of different error checking algorithms. All data-types may use the same type of error checking algorithm. Many embodiments are possible.

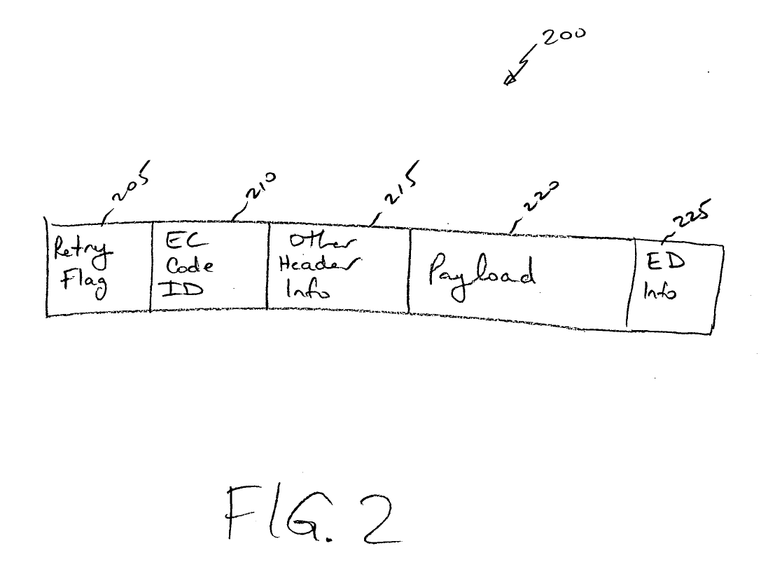

The packet encoder 140 of the transmitting computer system 105 may append additional bits to the header of each packet to indicate whether retransmissions should occur in the event of a packet error or bit error and to identify the EC algorithm used. The packet encoder 140 may also append error-detection information, such as CRC information, parity bits, etc. FIG. 2 illustrates an example packet 200, which includes a retry flag 205 (e.g., one bit) to indicate whether retransmissions should occur, an EC code ID (e.g., two bits) 210 to identify the EC code used, other header information 215, a payload 220, and error-detection (ED) information 225 to assist the receiving computer system 115 with determining whether an error in the data may exist. If the packet encoder 140 determines that the data is general data, then the packet encoder 140 may set the retry flag 205 to indicate that retransmissions may occur in the event of a packet or bit error. If the packet encoder 140 determines that the data is multimedia data, then the packet encoder 140 may set the retry flag 205 to indicate that retransmissions should not occur in the event of a packet or bit error.

The physical layer 130 of the transmitting computer system 105 includes a communication module 150 that transmits the packets, regardless of data-type, onto the computer network 110 to the receiving computer system 115.

The physical layer 165 of the receiving computer system 115 includes a communication module 185 that receives the data packets, regardless of data-type, from the computer network 110 and forwards the packets to the MAC layer 160 of the receiving computer 160.

The MAC layer 160 of the receiving computer system 115 includes a packet decoder 175 and a set of EC modules 180. In one embodiment, the set of EC modules 180 of the transmitting computer system 115 includes the set of EC modules 145 that the receiving computer system 105 implements. The packet decoder 175 conducts bit error checking (e.g., parity, repetition, CRC) and packet assembly. In the event of a bit or packet error, the packet decoder 175 requests a retransmission only if the retry flag 205 of the packet 200 indicates that a retransmission should occur. If the retry flag 205 indicates that a retransmission should not occur, then the packet decoder 175 reads the EC code ID 210 to determine whether to apply any error correction (or other error masking technique). If the EC code ID 210 identifies an EC algorithm, then the packet decoder 140 in coordination with the corresponding EC module 180 applies error correction to attempt to correct the packet or bit error. The MAC layer 160 forwards the packets, as corrected, to the upper layers 155 of the receiving computer system 115.

The upper layers 155 of the receiving computer system 115 includes a receiving (RX) application 170, which uses the data packets, e.g., to playback the video, voice or audio signal, to display the web page, to create the file, etc.

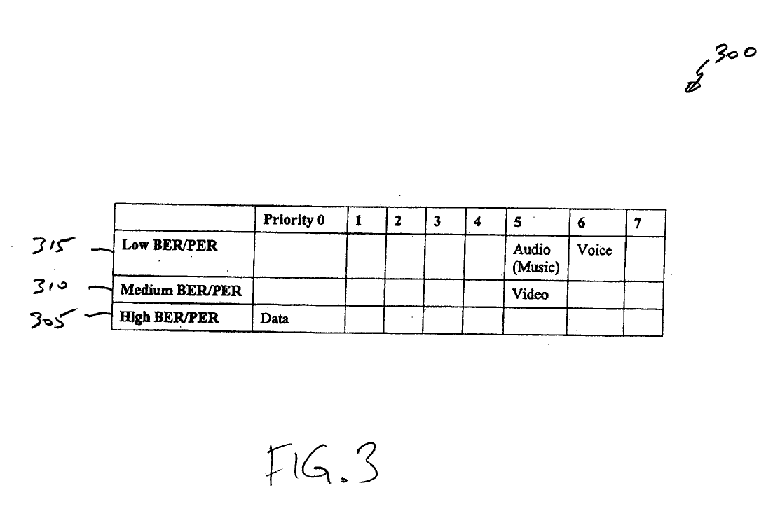

FIG. 3 illustrates an example two-dimensional QoS model 300, where priority level (0-7) is one dimension and PER and/or BER (Low, Medium, High) is the second dimension. As shown, general data may be set as low priority, e.g., priority level 0, meaning that high latency is acceptable. Audio and video data may be set as medium-high priority, e.g., priority level 5, meaning that minimal-to-no latency is preferred. Voice data may be set to high priority, e.g., priority level 6, meaning that no latency is preferred. Also, as shown, data may be set to tolerate high BER and/or PER and may be retransmitted. If data is set to tolerate high BER and/or PER, weak to no EC may be needed. As shown, video is set to tolerate some (medium) BER and/PER. Medium tolerance of BER and/or PER may be set not to allow retransmissions and to apply a medium-level EC algorithm (or multiple EC algorithms). Voice and audio is set to tolerate only low BER and/or PER. Low tolerance of BER and/or PER may be set not to allow retransmissions and to use a stronger EC algorithm (or multiple EC algorithms resulting in a stronger EC algorithm). Accordingly, for each data-type, a different EC algorithm may be used. It should be noted that the strength of the EC algorithm is balanced against the need for additional bandwidth to send the redundant information and possible delays should the EC algorithm require multiple packets to effect bit and/or packet error correction.

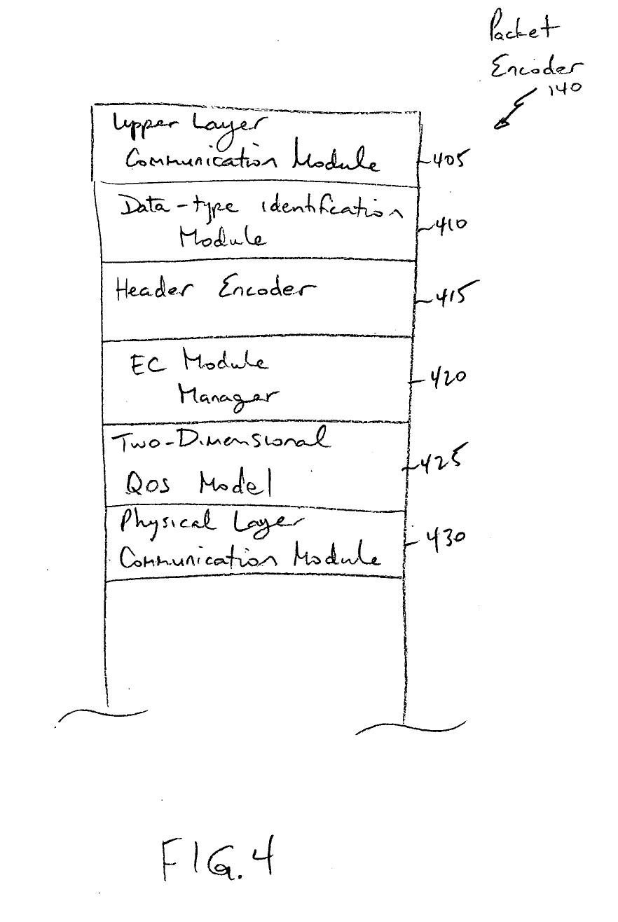

FIG. 4 is a block diagram illustrating details of the packet encoder 140, in accordance with an embodiment of the present invention. Packet encoder 140 includes an upper layer communication module 405, a data-type identification module 410, a header encoder 415, an EC module manager 420, a two-dimensional QoS model 425 (e.g., two-dimensional QoS model 300), and a physical layer communication module 430.

The upper layer communication module 405 obtains data from upper layers 120. The upper layer communication module 405 may include buffers, queues, etc. The data-type identification module 410 may determine the data-type from header information provided in the data. The header information may include priority information, data-type information, application-identification information, and/or the like. The header encoder 415, based on the data-type determined by the data-type identification module 405 and on the BER/PER settings for the data-types as defined in the two-dimensional QoS model 425, appends the retry flag 205 and the EC code ID 210 to the data from the upper layers 120. The header encoder 415 may also append other header information such as error-detection information, e.g., CRC, parity, etc. The EC module manager 420, based on the data-type and on the BER/PER settings for the data-types as defined in the two-dimensional QoS model 425, operates with the EC modules 145 to generate EC data packets or additional header information to be sent with the original data from the upper layers 120 to the receiving computer system 115. The physical layer communication module 430 uses the priority level settings for the data-types as defined in the two-dimensional QoS model 425 to prioritize the data packets for transmission to the physical layer 130. The physical layer communication module 430 forwards the data packets to the physical layer 130, as prioritized.

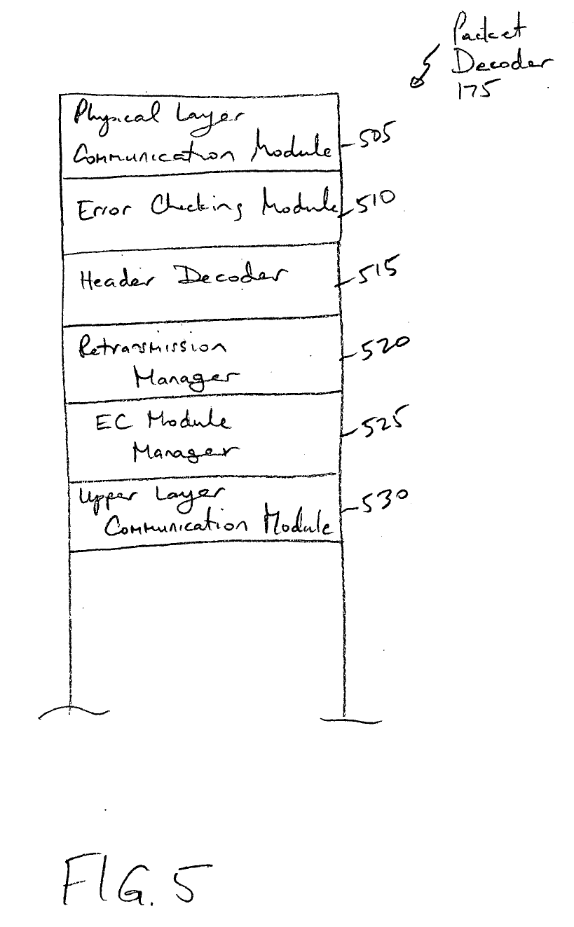

FIG. 5 is a block diagram illustrating details of the packet decoder 175, in accordance with an embodiment of the present invention. The packet decoder 175 includes a physical layer communication module 505, error checking module 510, header decoder 515, retransmission manager 520, EC module manager 525, and an upper layer communication module 530.

The physical layer communication module 505 receives data packets from the physical layer 165. The error checking module 510 performs bit/packet error checking, e.g., CRC, to detect any bit or packet errors. If an error exists, the header decoder 515 determines whether the retry flag 205 of the data packet 200 allows for retransmissions. If so, then the retransmission manager 520 initiates a retransmission request back to the physical layer communication module 505. If not, then the header decoder 515 identifies the EC code ID 210 in the packet header. The EC module manager 525 operates with the EC module 180 corresponding to the EC Code ID 210 to conduct error correction. The upper layers communication module 530 then forwards the data packets as assembled and corrected to the upper layers 155.

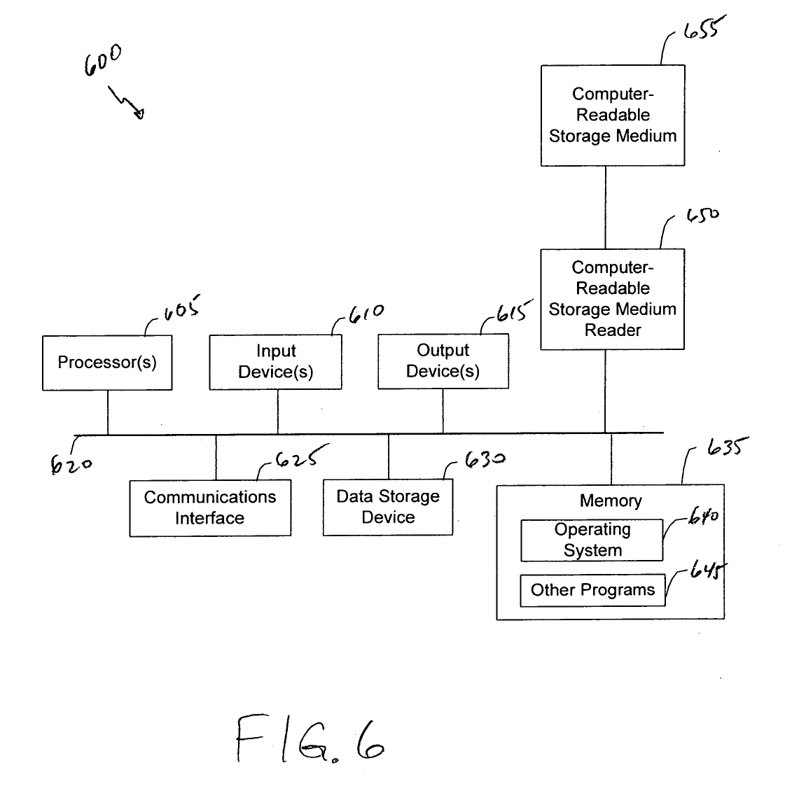

FIG. 6 is a block diagram illustrating details of a computer system 600, of which transmitting computer system 105 and receiving computer system 115 each may be an instance. Computer system 600 includes a processor 605, such as an Intel Pentium® microprocessor or a Motorola Power® microprocessor, coupled to a communications channel 620. The computer system 600 further includes an input device 610 such as a keyboard or mouse, an output device 615 such as a cathode ray tube display, a communications device 625, a data storage device 630 such as a magnetic disk, and memory 635 such as Random-Access Memory (RAM), each coupled to the communications channel 620. The communications interface 625 may be coupled to a network such as the wide-area network commonly referred to as the Internet. One skilled in the art will recognize that, although the data storage device 630 and memory 635 are illustrated as different units, the data storage device 630 and memory 635 can be parts of the same unit, distributed units, virtual memory, etc.

The data storage device 630 and/or memory 635 may store an operating system 640 such as the Microsoft Windows XP, Linux, the IBM OS/2 operating system, the MAC OS, or UNIX operating system and/or other programs 645. It will be appreciated that a preferred embodiment may also be implemented on platforms and operating systems other than those mentioned. An embodiment may be written using JAVA, C, and/or C++ language, or other programming languages, possibly using object oriented programming methodology.

One skilled in the art will recognize that the computer system 600 may also include additional information, such as network connections, additional memory, additional processors, LANs, input/output lines for transferring information across a hardware channel, the Internet or an intranet, etc. One skilled in the art will also recognize that the programs and data may be received by and stored in the system in alternative ways. For example, a computer-readable storage medium (CRSM) reader 650 such as a magnetic disk drive, hard disk drive, magneto-optical reader, CPU, etc. may be coupled to the communications bus 620 for reading a computer-readable storage medium (CRSM) 655 such as a magnetic disk, a hard disk, a magneto-optical disk, RAM, etc. Accordingly, the computer system 600 may receive programs and/or data via the CRSM reader 650. Further, it will be appreciated that the term “memory” herein is intended to cover all data storage media whether permanent or temporary.

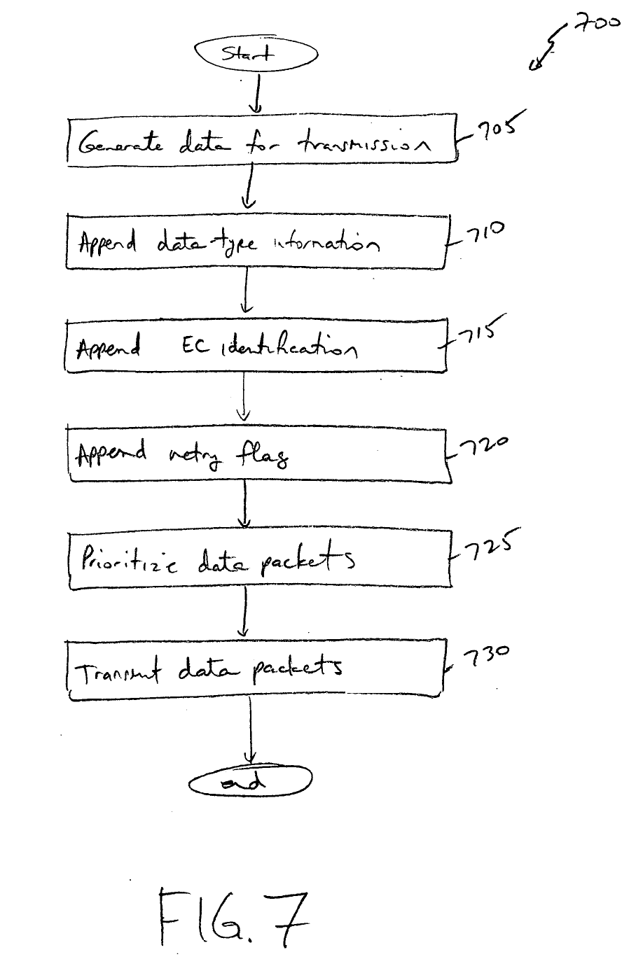

FIG. 7 is a flowchart illustrating a method 700 of encoding and transmitting data packets, in accordance with an embodiment of the present invention. Method 700 begins in step 705 with the transmission application 135 generating data for transmission. In step 710, the upper layers 120 append data-type information to the data. Based on the data-type and on a two-dimensional QoS model 425, the header encoder 415 of the packet encoder 140 in step 715 appends error correction code identification, e.g., EC code ID 210, and in step 720 appends retry flag information, e.g., retry flag 205, to the data packet 200. The physical layer communication module 430 in step 725 prioritizes the data packets, including any packets generated by the EC algorithm, to transmit to the physical layer 130. Prioritization may include any EDCA algorithms of 802.11e. The communication module 150 of the physical layer 130 in step 730 transmits the data packets as prioritized. Method 700 then ends.

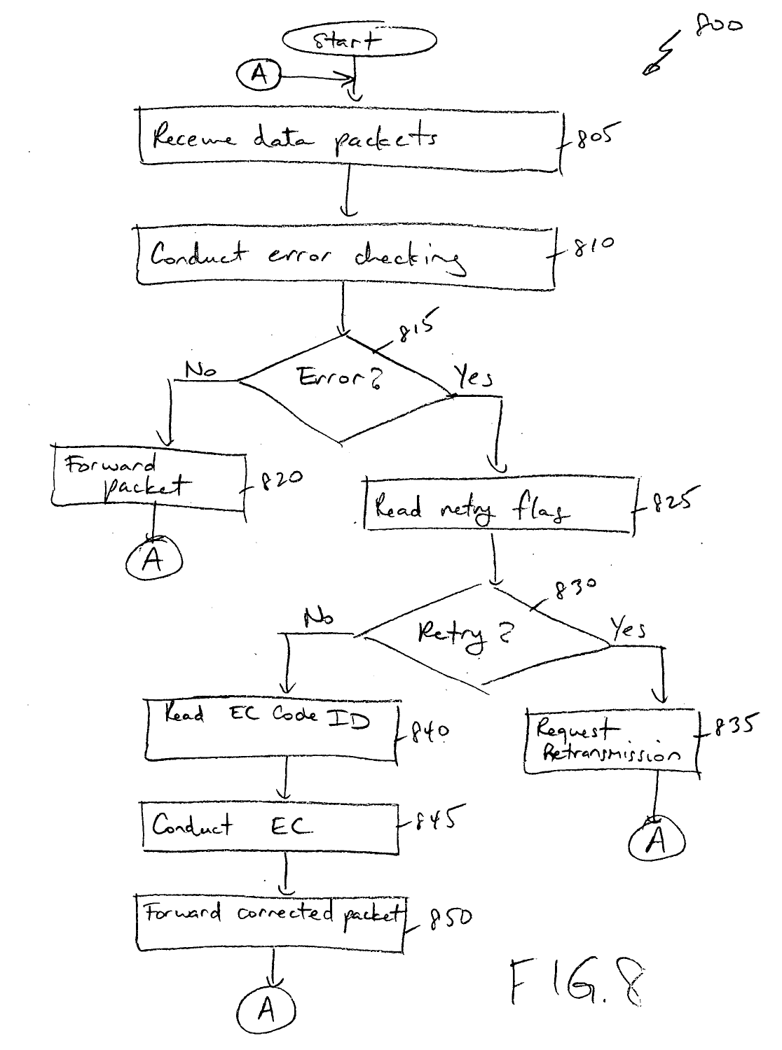

FIG. 8 is a flowchart illustrating a method 800 of receiving and decoding data packets, in accordance with an embodiment of the present invention. Method 800 begins in step 805 with the communication module 185 of the physical layer 165 receiving data packets and forwarding them to the physical layer communication module 505 of the MAC layer 160. The error checking module 510 of the MAC layer 160 in step 810 conducts error checking. In step 815, the error checking module 510 determines whether there was a bit or packet error. If not, then the upper layer communication module 530 in step 820 forwards the data packet or packets to the upper layers 155. If an error is detected, then the header decoder 515 in step 825 reads the retry flag 205 and in step 830 determines if the retry flag 205 allows retransmissions. If so, then the retransmission manager 520 in step 835 requests retransmission of the data packet or packets with the error or errors. If not, the header decoder 515 in step 840 reads the error correction module ID, e.g., EC code ID 210. The EC module manager 525 in step 845 conducts error correction, e.g., in coordination with one or more of the EC modules 180, to correct the noted error or errors. The upper layers communication module 530 in step 850 forwards the corrected packet to the upper layers 155. Method 800 then ends.

Although the embodiments above have been described as within the physical layer 130/165 or MAC layer 125/160, the principles of this invention may be applied to an upper layer 120/155. For example, the packet encoder 140, error correction modules 145/180 and the packet decoder 175 may be implemented in an upper layer 120/155.

The foregoing description of the preferred embodiments of the present invention is by way of example only, and other variations and modifications of the above-described embodiments and methods are possible in light of the foregoing teaching. Although the network sites are being described as separate and distinct sites, one skilled in the art will recognize that these sites may be a part of an integral site, may each include portions of multiple sites, or may include combinations of single and multiple sites. The various embodiments set forth herein may be implemented utilizing hardware, software, or any desired combination thereof. For that matter, any type of logic may be utilized which is capable of implementing the various functionality set forth herein. Components may be implemented using a programmed general purpose digital computer, using application specific integrated circuits, or using a network of interconnected conventional components and circuits. Connections may be wired, wireless, modem, etc. The embodiments described herein are not intended to be exhaustive or limiting. The present invention is limited only by the following claims.

1. A method comprising:
obtaining a data packet of a data-type to be transmitted via a computer network to a receiving system;
appending a retry flag to the data packet, the retry flag being based on the data-type, the retry flag indicating whether the receiving system should attempt a retransmission when an error is presumed in the data packet; and
transmitting the data packet with the appended retry flag via the computer network to the receiving system.

2. The method of claim 1, wherein the data-type is one of voice, video or audio data, and the retry flag indicates that the receiving system should not attempt retransmission when an error is presumed in the data packet.

3. The method of claim 1, further comprising appending error-detection information to the data packet, the error-detection information to be used for validation against the data packet by the receiving system, a failure of validation enabling the receiving system to presume an error in the data packet.

4. The method of claim 3, wherein the error-detection information includes CRC information.

5. The method of claim 1, further comprising appending an error-correction algorithm ID to the data packet.

6. The method of claim 5, further comprising selecting the error-correction algorithm ID to be appended to the data packet based on the data-type.

7. The method of claim 1, further comprising
using an error-correction algorithm to generate error-correction information associated with the data packet, the error-correction information intended to enable the receiving system to correct an error presumed in the data packet; and
transmitting the error-correction information associated with the data packet to the receiving system.

8. A system comprising:
an upper layer communication module for obtaining a data packet of a data-type to be transmitted via a computer network to a receiving system;
a header encoder for appending a retry flag to the data packet, the retry flag being based on the data-type, the retry flag indicating whether the receiving system should attempt a retransmission when an error is presumed in the data packet; and
a physical layer for transmitting the data packet with the appended retry flag via the computer network to the receiving system.

9. The system of claim 8, wherein the data-type is one of voice, video or audio data, and the retry flag indicates that the receiving system should not attempt retransmission when an error is presumed in the data packet.

10. The system of claim 8, wherein the header encoder appends error-detection information to the data packet, the error-detection information to be used for validation against the data packet by the receiving system, a failure of validation enabling the receiving system to presume an error in the data packet.

11. The system of claim 10, wherein the error-detection information includes CRC information.

12. The system of claim 8, wherein the header encoder appends an error-correction algorithm ID to the data packet.

13. The system of claim 12, wherein the header encoder accesses a QoS model defining which error-correction algorithm ID to append to the data packet based on the data-type.

14. The system of claim 8,
further comprising an error-correction module for using an error-correction algorithm to generate error-correction information associated with the data packet, the error-correction information intended to enable the receiving system to correct an error presumed in the data packet; and
wherein the physical layer transmits the error-correction information associated with the data packet to the receiving system.

15. A method comprising:
receiving a data packet having error-detection information and a retry flag;
validating the error-detection information against the data packet;
when the error-detection information fails to validate, presuming that the data packet contains an error; and
when presuming that the data packet contains an error, initiating a retransmission if the retry flag indicates that a retransmission should occur and not initiating a retransmission if the retry flag indicates that a retransmission should not occur.

16. The method of claim 15, further comprising
when presuming that the data packet contains an error and the retry flag indicates that a retransmission should not occur, initiating an error correction algorithm to attempt to correct the error.

17. The method of claim 16, wherein the data packet has an error-correction algorithm ID that identifies the error correction algorithm.

18. A system comprising:
a physical layer for receiving a data packet having error-detection information and a retry flag;
an error checking module for validating the error-detection information against the data packet and presuming that the data packet contains an error when the error-detection information fails to validate;
a retransmission manager for initiating a retransmission when presuming that the data packet contains an error and the retry flag indicates that a retransmission should occur, and not initiating a retransmission when presuming that the data packet contains an error and the retry flag indicates that a retransmission should not occur.

19. The system of claim 18, further comprising an error correction module for initiating an error correction algorithm to attempt to correct the error when presuming that the data packet contains an error and the retry flag indicates that a retransmission should not occur.

20. The system of claim 18, wherein the data packet has an error-correction algorithm ID that identifies the error correction algorithm.
